(19) United States
(12) Patent Application Publication
(10) Pub. No.: US 2026/0130240 A1
(43) Pub. Date: May 7, 2026

(54) ELECTRONIC DEVICE AND METHOD FOR MANUFACTURING THE SAME

(71) Applicant: InnoLux Corporation, Miao-Li County (TW)

(72) Inventors: Po-Yun HSU, Miao-Li County (TW); Meng-Hsuan Chuang, Miao-Li County (TW)

(73) Assignee: InnoLux Corporation, Miao-Li County (TW)

(21) Appl. No.: 19/351,251

(22) Filed: Oct. 6, 2025

Related U.S. Application Data
(60) Provisional application No. 63/716,244, filed on Nov. 5, 2024.

(30) Foreign Application Priority Data
Jun. 13, 2025 (CN) 202510788849.8

(51) Int. Cl. H01L 23/538; H01L 21/48; H01L 23/00; H01L 23/498; H01L 25/065

(52) U.S. Cl. CPC H10W 70/611; H10W 70/095; H10W 70/635; H10W 90/00; H10W 90/701; H10W 74/15; H10W 90/724; H10W 90/733; H10W 90/734

(57) ABSTRACT

A method for manufacturing an electronic device includes steps as follows. A substrate is provided. A first mask is provided on a first surface of the substrate. The first mask is patterned to form a first opening in the first mask, and the first opening exposes a corresponding portion of the substrate. A light source including a first energy is provided to the corresponding portion of the substrate to perform a first modification step, so as to form a first modified region in the substrate. Another light source including a second energy is provided to the corresponding portion of the substrate to perform a second modification step, so as to form a second modified region in the substrate. The second modified region at least partially overlaps the first modified region.

### CROSS REFERENCE TO RELATED APPLICATION

This application claims the benefit of U.S. Provisional Application No. 63/716,244, filed on Nov. 5, 2024. The content of the application is incorporated herein by reference.

### BACKGROUND OF THE DISCLOSURE

### 1. Field of the Disclosure

The present disclosure relates to an electronic device and a method for manufacturing the same, and more particularly, to an electronic device including a substrate with a through hole and a method for manufacturing the same.

### 2. Description of the Prior Art

In the field of integrated circuits, electronic devices may need to be configured with larger dimensions (e.g., larger areas) and more layers according to different applications and requirements. The aforementioned layers may include, for example, carriers used in the manufacturing process, substrate structures and redistribution layers as part of the final product. For example, using a large-area carrier in production is beneficial for increasing the output rate of packaging units or reducing manufacturing costs. However, when the dimension of the electronic device increases and the number of layers increases, the warpage degree of the electronic device also increases significantly.

In order to reduce the warpage degree, a substrate with higher rigidity or insulating properties may be used. However, when forming through holes in the substrate with higher rigidity or insulating properties, it is easy to affect the yield of through holes due to incomplete modification, which in turn affects the yield of the electronic devices.

### SUMMARY OF THE DISCLOSURE

According to an embodiment of the present disclosure, a method for manufacturing an electronic device includes steps as follows. A substrate is provided. A first mask is provided on a first surface of the substrate. The first mask is patterned to form a first opening in the first mask, and the first opening exposes a corresponding portion of the substrate. A light source including a first energy is provided to the corresponding portion of the substrate to perform a first modification step, so as to form a first modified region in the substrate. Another light source including a second energy is provided to the corresponding portion of the substrate to perform a second modification step, so as to form a second modified region in the substrate. The second modified region at least partially overlaps the first modified region.

According to another embodiment of the present disclosure, an electronic device includes a substrate and a conductive layer. The substrate has a through hole. In a cross-sectional view of the substrate, a hole wall of the through hole has a wavy profile, and the wavy profile extends along a normal direction of the substrate. The conductive layer is disposed in the through hole.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1, FIG. 2, FIG. 3, FIG. 4 and FIG. 5 are cross-sectional schematic diagrams showing steps of a method for manufacturing an electronic device according to an embodiment of the present disclosure.

FIG. 6 is an enlarged schematic diagram of Part A1 in FIG. 4.

FIG. 7 is a cross-sectional schematic diagram showing a step of a method for manufacturing an electronic device according to another embodiment of the present disclosure.

FIG. 8 is a cross-sectional schematic diagram showing a step of a method for manufacturing an electronic device according to yet another embodiment of the present disclosure.

FIG. 9 is a cross-sectional schematic diagram of an electronic device according to an embodiment of the present disclosure.

FIG. 10 is a cross-sectional schematic diagram of an electronic device according to another embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include/comprise” and “have” are used in an open-ended fashion, and thus should be interpreted to mean “include, but not limited thereto . . . ”.

In the present disclosure, the directional terms, such as “on/up/above”, “down/below”, “front”, “rear/back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, when a structure (or layer, or component, or substrate) is described as located on/above another structure (or layer, or component, or substrate), it may refer that the two structures are adjacent and directly connected to each other, or the two structures are adjacent and indirectly connected to each other. The two structures being indirectly connected to each other may refer that at least one intervening structure (or intervening layer, or intervening component, or intervening substrate, or intervening interval) exists between the two structures, a lower surface of one of the two structure is adjacent or directly connected to an upper surface of the intervening structure, and an upper surface of the other of the two structures is adjacent or directly connected to a lower surface of the intervening structure. The intervening structure may be a single-layer or multi-layer physical structure or a non-physical structure, and the present disclosure is not limited thereto. In the present disclosure, when a certain structure is disposed “on/above” other structures, it may refer that the certain structure is “directly” disposed on/above the other structures, or the certain structure is “indirectly” disposed on/above the other structures, i.e., at least one structure is disposed between the certain structure and the other structures.

In the present disclosure, the term “connection” may include physical connection or electrical connection, and may include direct contact or indirect contact.

In the present disclosure, the term “disposed on” is used for convenience of description and does not limit the process steps or sequence.

The terms “equal”, “identical/the same”, or “substantially/approximately” mentioned in this document generally mean being within 20% of a given value or range, or being within 10%, 5%, 3%, 2%, 1% or 0.5% of the given value or range.

Furthermore, any two values or directions used for comparison may have a certain error. If a first value is equal to a second value, it implies that there may be an error of about 10% between the first value and the second value; if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

Although ordinal numbers such as “first”, “second”, etc., may be used to describe elements in the description and the claims, it does not imply and represent that there have other previous ordinal number. The ordinal numbers do not represent the order of the elements or the manufacturing order of the elements. The ordinal numbers are only used for discriminate an element with a certain designation from another element with the same designation. The claims and the description may not use the same terms. Accordingly, a first element in the description may be a second element in the claims.

In addition, the term “a given range is from a first value to the second value” or “a given range falls within a range from a first value to a second value” refers that the given range includes the first value, the second value and other values therebetween.

In the present disclosure, “an element surrounds another element” may refer that in a cross-sectional view, the element at least contacts a side surface of the another element.

In the present disclosure, the process for manufacturing the electronic device may be, for example, applied to a wafer-level package (WLP) process or a panel-level package (PLP) process, and may be a chip first process or a chip last (i.e., RDL first) process.

The electronic device of the present disclosure may be applied to a power module, a semiconductor package device, a display device, a light emitting device, a backlight device, an antenna device, a sensing device or a tiled device, but not limited thereto. The display device may be a non-self-luminous type display device or a self-luminous type display device. The antenna device may be a liquid-crystal-type antenna device or a non-liquid-crystal-type antenna device. The sensing device may be a device for sensing capacitance, light, thermal or ultrasonic, but not limited thereto. The electronic elements of the electronic device may include passive elements and active elements, such as capacitors, resistors, inductors, diodes and transistors. The diode may include a light emitting diode (LED) or a photodiode. The light emitting diode may include organic light emitting diode (OLED), mini LED, micro LED or quantum dot LED, but not limited thereto. The tiled device may exemplarily be a tiled display device or a tiled antenna device, but not limited thereto. Furthermore, the electronic devices may be foldable or flexible electronic devices. The electronic device may be any combination of aforementioned devices, but not limited thereto. Furthermore, a shape of the electronic device may be a rectangle, a circle, a polygon, a shape with curved edge or other suitable shapes. The electronic device may have peripheral systems, such as a driving system, a control system and a light system for supporting the display device, the antenna device, the wearable device (for example, including augmented reality (AR) device or virtual reality (VR) device), the vehicle-mounted device (for example, including car windshields) or the tiled device.

In the present disclosure, the chip may include an active surface having a pad and a back surface opposite to the active surface.

In the present disclosure, the redistribution layer structure may be electrically connected with each of the chips or electronic units through bonding elements, such as bumps, solder balls or pads. The redistribution layer structure may include at least one conductive layer and at least one insulating layer. The redistribution layer structure may be configured to redistribute circuits and/or further increase the circuit fan-out area, or different electronic elements may be electrically connected with each other through the redistribution layer structure. The method of forming the redistribution layer structure may include providing a stack of at least one insulating layer and at least one conductive layer, and may include processes such as photolithography, etching, surface treatment, laser and electroplating. The surface treatment may include roughening the surface of the insulating layer or the surface of the conductive layer to improve the bonding ability thereof. Alternatively, the redistribution layer structure may serve as a substrate for routing electrical interface between one connection and another connection. The purpose of the redistribution layer structure is to fan out the connection to allow the connection to have a wider pitch or to redistribute the connection to another connection with a different pitch.

In the present disclosure, the term “modification” may refer to reduce or weaken a mechanical strength of a modified portion through appropriate processing methods.

In the present disclosure, it should be understood that a depth, a thickness, a width or a height of each element, or a spaced distance or a distance between elements may be measured by an optical microscopy (OM), a scanning electron microscope (SEM), a film thickness profiler (α-step), an ellipsometer or other suitable methods. In some embodiments, a cross-sectional image including elements to be measured can be obtained by the SEM, and the depth, the thickness, the width or the height of each element, or the spaced distance or the distance between elements can be measured thereby.

In the present disclosure, the definition of roughness may be as follow. For example, a surface is observed by the SEM. When a distance difference of 0.15 μm to 1 μm is between the crest point and the trough point of the surface undulation on the surface to be observed, the surface to be observed is determined to be rough. In the present disclosure, the determination of roughness, for example, may use a SEM or a transmission electron microscope (TEM) to observe the surface undulation at a same appropriate magnification, and the undulation degree are compared by taking a unit length (such as 10 μm). Herein, “appropriate magnification” may refer that at least 10 undulating peaks can be seen on at least one surface under the field of view of the magnification.

It should be noted that the technical features in different embodiments described in the following can be replaced, recombined, or mixed with one another to constitute another embodiment without departing from the spirit of the present disclosure.

Unless otherwise defined, all terms (including technical and scientific terms) used herein have the same meaning as commonly understood by a person having ordinary skill in the art to which the present disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the numbers of elements in the electronic devices shown in the following drawings, such as substrates, circuit structures, electronic units, carriers, through holes, conductive elements, pads, bonding elements, marking elements, heat spreaders, are only for illustration and are not limited thereby.

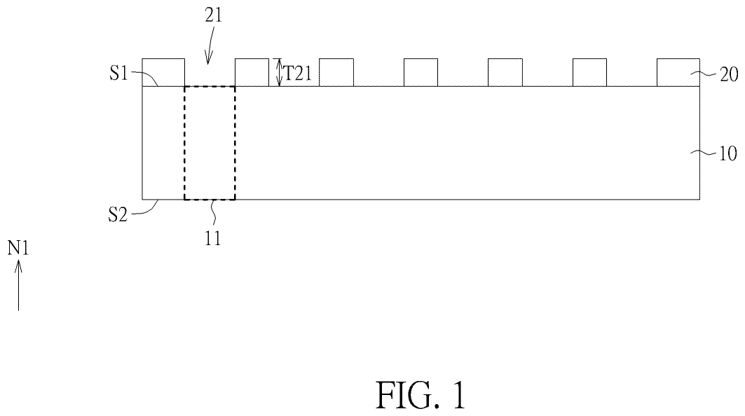

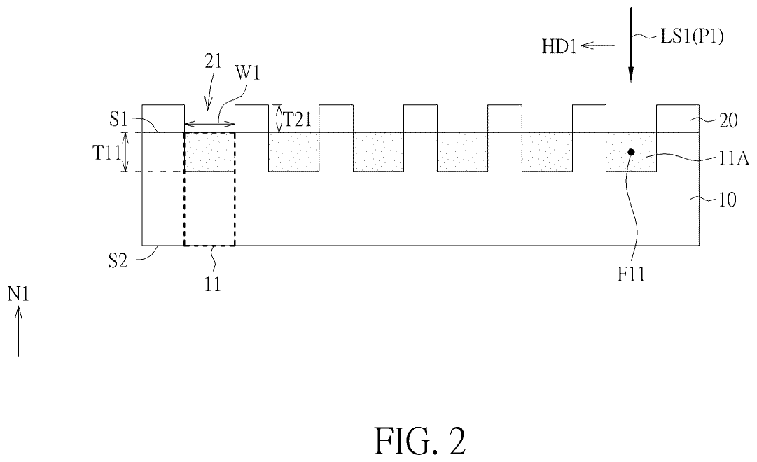

Please refer to FIG. 1 to FIG. 6, which are cross-sectional schematic diagrams showing steps of a method for manufacturing an electronic device according to an embodiment of the present disclosure. The method for manufacturing the electronic device may include steps as follows. As shown in FIG. 1, a substrate 10 is provided first. The substrate 10 has a surface S1 and a surface S2, the surface S2 is opposite to the surface S1, and the substrate 10 defines a normal direction (the direction N1). A material of the substrate 10 may include, for example, glass, flame retardant 4 (FR4 ), silicon, other suitable materials, or a combination thereof, but not limited thereto. In some embodiments, the substrate 10 may include transparent materials. For example, the substrate 10 may be a glass substrate. A material of the glass substrate may include silicon dioxide (SiO₂), boron trioxide (B₂O₃), aluminum oxide (Al₂O₃), metal oxides, a combination thereof, or other suitable materials, but not limited thereto. For example, a glass composition for forming the glass substrate may include from 50 weight percent (wt %) to 90 wt % of silicon dioxide (SiO₂), from 3 wt % to 15 wt % of boron trioxide (B₂O₃), from 0.5 wt % to 25 wt % of aluminum oxide (Al₂O₃), and other metal oxides with a content less than or equal to 20 wt %, such as oxides of alkali metals and oxides of alkaline earth metals. Thereby, it is beneficial to improve the rigidity of the substrate 10, but not limited thereto. In some embodiments, the substrate 10 has a transmittance ranging from 75% to 99.9% for light with a wavelength ranging from 280 nanometers (nm) to 400 nm. Thereby, it is beneficial for the light with the wavelength ranging from 280 nm to 400 nm to penetrate the substrate 10, but not limited thereto.

Next, a mask 20 is provided on the surface S1 of the substrate 10. For example, the mask 20 covers at least a portion of the surface S1. The mask 20, for example, may be made of a material that can absorb a laser beam (such as the laser beam LS1 in FIG. 2), i.e. the mask 20 may be used as a laser absorbing layer and/or a laser blocking layer, and the laser beam cannot penetrate the mask 20. In some embodiments, a transmittance of the mask 20 for light with a wavelength ranging from 280 nm to 400 nm is less than or equal to 1%, but not limited thereto. The thickness T21 of the mask 20, for example, may be greater than or equal to 0.01 μm and less than or equal to 5 μm, but not limited thereto. The thickness T21 may be a thickness of the mask 20 measured in the normal direction (the direction N1) of the substrate 10. In some embodiments, a material of the mask 20 may include silicon, silicon carbide (Si—C), nickel monoxide (NiO), tin dioxide (SnO₂), titanium dioxide (TiO₂), an oxide, other suitable materials, or a combination thereof, but not limited thereto. The term “cover” in the present disclosure refers that the mask 20 can overlap at least a portion of the substrate 10 in a projection direction or in the normal direction (the direction N1) of the substrate 10. In other words, the mask 20 may directly contact the surface S1 of the substrate 10 or do not directly contact the surface S1 of the substrate 10.

Next, the mask 20 is patterned to form an opening 21 in the mask 20, and the opening 21 exposes a corresponding portion 11 of the substrate 10, such as the portion surrounded by the dotted line in FIG. 1. Specifically, in the vertical direction (the direction N1), the left edge and the right edge of the corresponding portion 11 are respectively aligned with the left edge and the right edge of the corresponding opening 21, and the front edge (not shown) and the rear edge (not shown) of the corresponding portion 11 are respectively aligned with the front edge (not shown) and the rear edge (not shown) of the corresponding opening 21. In the present embodiment, the number of the openings 21 is plural, and the substrate 10 has a plurality of corresponding portions 11 corresponding to the openings 21. That is, the number of the openings 21 is the same as the number of the corresponding portions 11. Herein, the number of the openings 21 is six and the number of the corresponding portions 11 is six as an example, but not limited thereto. The numbers of the openings 21 and the corresponding portions 11 may be adjusted according to actual needs. In some embodiments, the process for patterning the mask 20, for example (but not limited thereto), may be an exposure and development process, which includes performing an exposure process to the mask 20 with a photomask to define the pattern of the openings 21, followed by performing a development process to the mask 20 to remove portions of the mask 20 to form the openings 21. In other embodiments, the process for patterning the mask 20, for example (but not limited thereto), may be an exposure and etching process, which includes first forming a photoresist on the mask 20, performing an exposure and development process to remove portions of the photoresist to define the pattern of the openings 21, removing portions of the mask 20 to form the openings 21 with the patterned photoresist as an etching mask, and then removing the photoresist. According to some embodiments, a maskless process may be used, such as patterning through laser direct imaging (LDI), but not limited thereto.

Next, as shown in FIG. 2, a light source including an energy P1 is provided to the corresponding portion 11 of the substrate 10 to perform a modification step, so as to form the modified region 11A in the substrate 10. Herein, the energy P1 is provided by irradiating the substrate 10 with the laser beam LS1. For example, the laser beam LS1 may irradiate the substrate 10 in the vertical direction, and may scan the substrate 10 from one side to another side along a direction, such as from right to left along the horizontal direction HD1, so that the plurality of corresponding portions 11 are modified to formed a plurality of modified regions 11A respectively in the plurality of the corresponding portions 11, but not limited thereto. In some embodiments, the laser beam LS1 may scan the substrate 10 from left to right in the horizontal direction HD1. Alternatively, the laser beam LS1 may scan the substrate 10 in other horizontal directions perpendicular to the normal direction (the direction N1) of the substrate 10. The vertical direction mentioned above, for example, may be opposite to the normal direction (the direction N1) of the substrate 10, and the horizontal direction HD1 may be perpendicular to the normal direction (the direction N1) of the substrate 10. Since the mask 20 may be made of a material that can absorb the laser beam LS1, the mask 20 can block the laser beam LS1. Accordingly, the corresponding portions 11 exposed from the openings 21 will be modified by the laser beam LS1, while the portions covered by the mask 20 will not or substantially not modified by the laser beam LS1. That is, the portion covered by the mask 20 and modified by the laser beam LS1 shall be less than or equal to half of the width W1 of the opening 21. In the present disclosure, a width of an element may refer to a length of the element in the horizontal direction perpendicular to the vertical direction (the direction N1). The wavelength of the laser beam LS1, for example, may range from 200 nm to 400 nm, but not limited thereto. The laser beam LS1 may have a depth of focus T11, and the laser beam LS1 may have a focal point F11. In the vertical direction (the direction N1), the focal point F11 is at the midpoint of the depth of focus T11. In some embodiments, the depth of focus T11 may range from 0.1 μm to 2 mm, but not limited thereto.

Next, as shown in FIG. 3, another light source including an energy P2 is provided to the corresponding portion 11 of the substrate 10 to perform another modification step, so as to form another modified region 11B in the substrate 10, wherein the modified region 11B at least partially overlaps the modified region 11A. Herein, the energy P2 is provided by irradiating the substrate 10 with the laser beam LS2. For example, the laser beam LS2 may irradiate the substrate 10 in the vertical direction (opposite to the direction N1), and may scan the substrate 10 from right to left along the horizontal direction HD1, so that the plurality of corresponding portions 11 are modified to formed a plurality of modified regions 11B respectively in the plurality of the corresponding portions 11. The wavelength of the laser beam LS2, for example, may range from 200 nm to 400 nm, but not limited thereto. The laser beam LS2 may have a depth of focus T12, and the laser beam LS2 may have a focal point F12. In the vertical direction (the direction N1), the focal point F12 is located at the midpoint of the depth of focus T12, and the focal point F12 is located below the focal point F11. In some embodiments, the depth of focus T12 may range from 0.1 μm to 2 mm, but not limited thereto. In addition, the depth of focus T11 may be the same or different from the depth of focus T12.

In a cross-sectional view of the substrate 10, the first modified region 11A and the second modified region 11B have an overlapping area AA1, and the proportion of the overlapping area AA1 in the first modified region 11A may range from 5% to 20% (5%≤AA1/11A≤20%), but not limited thereto. In some embodiments, a ratio of the first energy to the second energy may range from 0.8 to 1.2, which can improve the stability of the modification or improve the reliability of the device, but not limited thereto. In the present disclosure, the proportion of the overlapping area AA1 may be calculated as a ratio of the integrated area of the overlapping area AA1 to the integrated area of the modified region 11A, and the integrated area may be obtained by multiplying the length and the width as observed in a cross-sectional view.

Next, the step as shown in FIG. 3 may be repeated. That is, the energy (not shown) may continue to be provided to the corresponding portion 11 of the substrate 10 to perform the modification step, so as to form other modified regions (not shown) in the substrate 10, until the corresponding portion 11 of the substrate 10 is completely modified. It should be noted that the depth of focus and the focal point of the laser beam may be adjusted in each time, so that the modified region in each time may get closer to the surface S2, meanwhile the modified region may partially overlap the previously modified region. Thereby, the entire corresponding portion 11 can be modified, and the risk of incomplete modification of the corresponding portion 11 can be reduced, which is beneficial to increase the removal rate of the modified region in the subsequent etching process (see FIG. 4), so as to form a through hole TV0 with a well-defined profile in the substrate 10. The aforementioned energy may be provided by irradiating the substrate 10 with a laser beam. For details of the laser beam, references may be made to the relevant descriptions of the laser beam LS1 and the laser beam LS2. The wavelength of the laser beam of each modification step may independently be the same or different, and the depth of focus of the laser beam of each modification step may be independently the same or different.

In the present embodiment, the region of the substrate 10 to be modified (i.e., the corresponding portion 11) is defined by the opening 21 of the mask 20, and then the substrate 10 is scanned by the energy, so that the corresponding portion 11 of the substrate 10 exposed from the opening 21 is modified, but not limited thereto. In other embodiments, the energy source can be controlled to move to the region to be modified, and then the energy is provided to modify the region to be modified. For example, the laser source may be moved to the region to be modified through an external mechanism, and then the laser source is control to provide the laser beam to modify the region to be modified.

Next, as shown in FIG. 4, the modified region 11A, the modified region 11B, and other modified regions are removed to form a through hole TV0 in the substrate 10. For example, the modified region 11A, the modified region 11B, and other modified regions may be removed through an etching process. The etching process may be, for example, a wet etching process or an isotropic etching process, but not limited thereto. Afterward, the mask 20 may be removed, for example, by a wet stripping method using a solvent cleaning process, or by an O₂ plasma ashing method using oxygen plasma, or by other suitable processing methods, but not limited thereto.

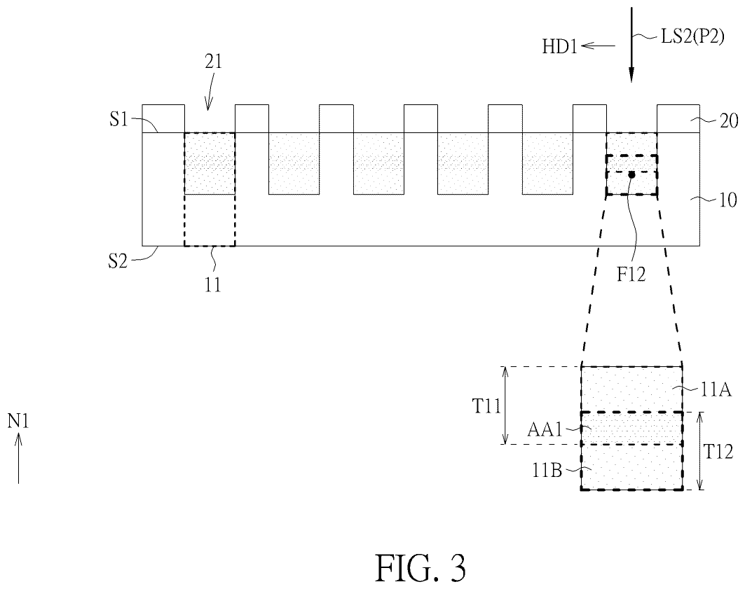

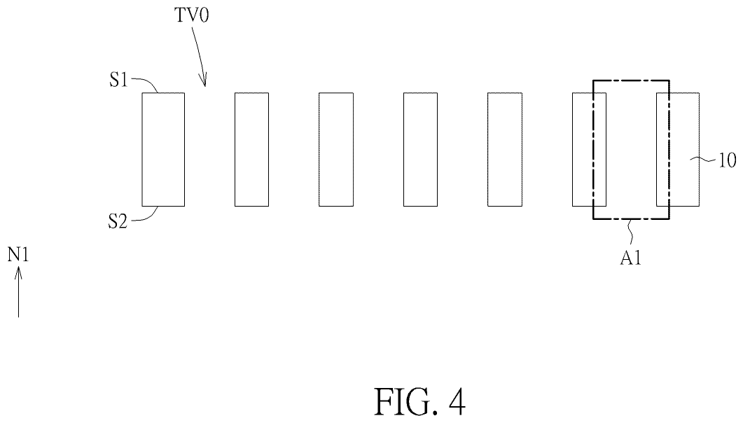

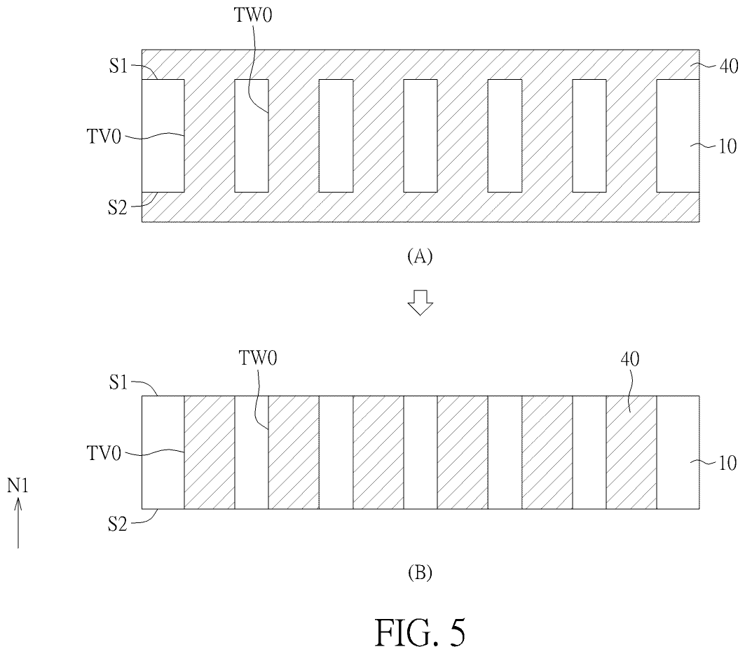

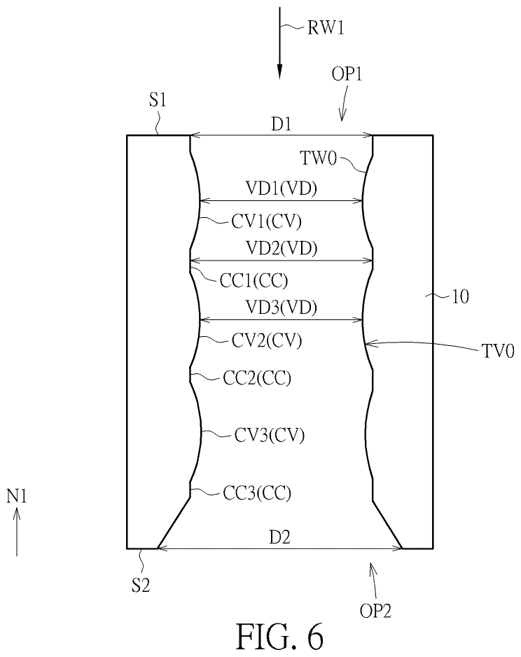

Please also refer to FIG. 6, which is an enlarged schematic diagram of Part A1 in FIG. 4. The through hole TV0 has a through-hole opening OP1 on the surface S1, and the through hole TV0 has a through-hole opening OP2 on the surface S2. The through-hole opening OP1 has a diameter D1, and the through-hole opening OP2 has a diameter D2. In some embodiments, the method for manufacturing the electronic device may further include a through hole detection step to measure the diameter D1 and the diameter D2 of each through hole TV0. When an absolute value of a difference between the diameter D2 and the diameter D1 is greater than 3 μm (i.e., the following condition is satisfied: |D2−D1|>3 μm), the method for manufacturing the electronic device further includes performing a rework step RW1, wherein the substrate 10 is subjected to a local etching process or a local laser process, so that the absolute value of the difference between the diameter D2 and the diameter D1 is equal to or less than 3 μm. That is, the following condition may be satisfied: |D2−D1|≤3 μm. Thereby, it is beneficial to optimize the shape of the through hole TV0, which is beneficial to improve the yield of the electronic device subsequently formed. In some embodiments, a ratio of the diameter D1 to the diameter D2 may range from 0.8 to 1.25. The diameter D1, for example, may range from 5 μm to 300 μm.

In FIG. 6, in a cross-sectional view of the substrate 10, the hole wall TW0 of the through hole TV0 may have a wavy profile, and the wavy profile extends along the normal direction (the direction N1) of the substrate 100. The wavy profile includes at least two convex portions CV and a concave portion CC disposed alternatively along the normal direction. That is, one convex portion CV, one concave portion CC and one convex portion CV are disposed sequentially along the depth direction. The convex portions CV protrude toward the through hole TV0 in a radial direction of the through hole TV0, and the concave portion CC concaves away from the through hole TV0 in the radial direction of the through hole TV0. Herein, the wave profile includes a convex portion CV1, a concave portion CC1, a convex portion CV2, a concave portion CC2, a convex portion CV3, and a concave portion CC3 disposed sequentially along the depth direction as an example, but not limited thereto. The number of convex portions CV and the number of the concave portions CC may be adjusted according to the number of the modification steps.

In detail, the number of the convex portions CV may correspond to the number of the modified regions, while the number of the concave portions CC may correspond to the number of the overlapping regions of the plurality of modified regions. For example, the convex portion CV1 corresponds to the modified region 11A, the convex portion CV2 corresponds to the modified region 11B, and the concave portion CC1 corresponds to the overlapping region of the modified region 11A and the modified region 11B. On the other hand, the through hole TV0 may include different diameters VD corresponding to the convex portion CV and the concave portion CC. The diameter VD of the through hole TV0 corresponding to the convex portion CV may be less than the diameter VD of the through hole TV0 corresponding to the concave portion CC. For example, the through hole TV0 has a diameter VD1 corresponding to the convex portion CV1, the through hole TV0 has a diameter VD2 corresponding to the concave portion CC1, the through hole TV0 has a diameter VD3 corresponding to the convex portion CV2, the diameter VD2 is greater than the diameter VD1, and the diameter VD2 is greater than the diameter VD3, but not limited thereto. Because the overlapping region is subjected at least two modification steps, the overlapping region is prone to have a larger diameter VD. In some embodiments, in the cross-sectional view of the substrate 10, the convex portion CV may have a convex curved profile, while the concave portion CC may have a relatively flatter profile. In other words, the curvature of the convex portion CV may be greater than that of the concave portion CC, but not limited thereto.

In some embodiments, the hole wall TW0 of the through hole TV0 may have a surface roughness Rz, and the following condition may be satisfied: 0.1 μm≤Rz≤1.5 μm.

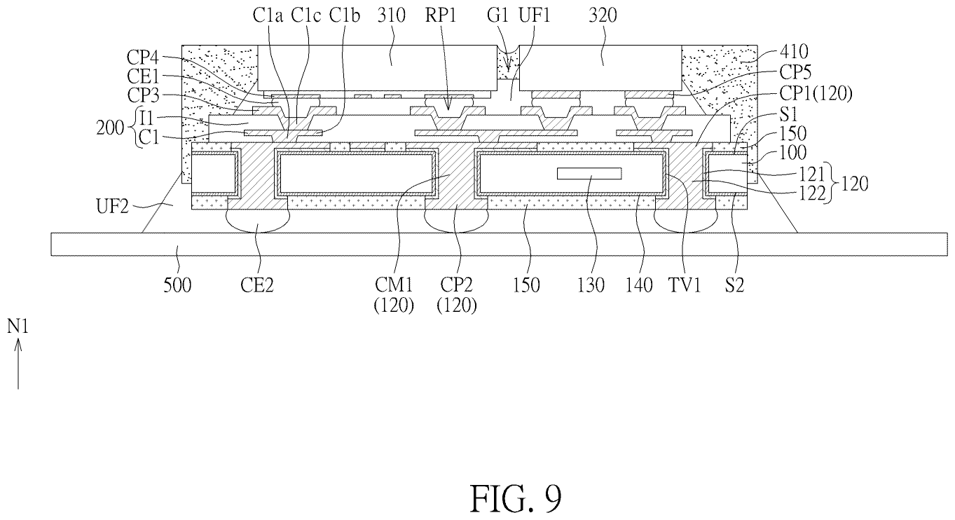

Next, as shown in FIG. 5, a conductive layer 40 disposed in the through hole TV0 is provided. Herein, the conductive layer 40 is a single-layer structure as an example. First, as shown in the part (A) of FIG. 5, a conductor layer at least fills the through hole TV0 and covers the surface S1 and the surface S2 of the substrate 10 may be formed by an electroplating process, a chemical electroplating process, a physical vapor deposition process or other suitable processes. The conductor layer may serve as the conductive layer 40. That is, a ratio of the volume of the conductive layer 40 in the through hole TV0 to the volume of the through hole TV0 may be greater than or equal to 0.9. In some embodiments, the conductive layer 40 may be a multi-layer structure. For example, the conductive layer 40 may include a seed layer (see the seed layer 121 in FIG. 9) and a conductor layer (see the conductor layer 122 in FIG. 9). In this case, a seed layer conformally covering the surface S1 and the surface S2 of the substrate 10 and the hole wall TW0 of the through hole TV0 may be firstly formed by an electroplating process, a chemical electroplating process, a physical vapor deposition process or other suitable processes, and then a conductor layer filling the through hole TV0 and covering the surface S1 and the surface S2 of the substrate 10 are formed by an electroplating process, a chemical electroplating process, a physical vapor deposition process or other suitable processes. In this case, the seed layer and the conductor layer together serve the conductive layer 40. In some embodiments, a material of the conductor layer, for example, may include, iron, aluminum, copper, nickel, tungsten, gold, platinum, other suitable materials, or a combination thereof, but not limited thereto. A material of the seed layer, for example, may include titanium, tungsten, nickel, other suitable materials or a combination thereof. According to an embodiment, the seed layer may include titanium copper.

The method for manufacturing the electronic device may further include performing a planarization process to the conductive layer 40. As shown in the part (B) of FIG. 5, in some embodiments, the planarization process includes completely removing the portion of the conductive layer 40 on the surface S1 and/or the surface S2, which may be achieved by a grinding method, such as mechanical grinding, chemical mechanical polishing, other suitable methods, or a combination thereof. In other embodiments, the planarization process includes partially removing the portion of the conductive layer 40 on the surface S1 and/or the surface S2 (for example, may be removed by grinding and/or photolithography processes), and the portion of the conductive layer 40 reserved on the surface S1 and/or the surface S2 may serve as pads (see the pad CP1 and the pad CP2 in FIG. 9). Afterward, a planarization layer (see the planarization layer 150 in FIG. 9) is provided to cover the surface S1 and/or the surface S2 and the portion of the conductive layer 40 disposed on the surface S1 and/or the surface S2 (i.e., the portion that serves as pads). The planarization layer, for example, may be formed by an electroplating process, a chemical electroplating process, a physical vapor deposition process or other suitable processes. The portion of the planarization layer on the conductive layer 40 (i.e., the portion that serves as pads) is removed by a grinding method such as chemical mechanical polishing, so that the portion of the conductive layer 40 disposed on the surface S1 and/or the surface S2 (i.e., the portion that serves as pads) is exposed from the planarization layer, and the surface of the portion of the conductive layer 40 disposed on the surface S1 and/or the surface S2 (i.e., the portion that serves as pads) away from the surface of the substrate 10 is aligned with the surface of the planarization layer away from the surface of the substrate 10. The surface roughness of the planarization layer may be less than the surface roughness of the conductive layer 40. A material of the planarization layer may include an organic material or an inorganic material. The organic material may include, polymers, resins, polyimides, polycyclic aromatic hydrocarbons, other suitable materials, or a combination thereof, but not limited thereto. The inorganic material may include silicon oxide, titanium oxide, alumina, other suitable materials, or a combination thereof, but not limited thereto.

In some embodiments, before providing the conductive layer 40 disposed in the through hole TV0, a buffer layer (see the buffer layer 140 in FIG. 9) may be provided to cover at least one of the surface S1, the surface S2 and the hole wall TV0 of the through hole TV of the substrate 10. With the buffer layer, it is beneficial to reduce the probability of the generation of microcracks in the substrate 10, but not limited thereto. The buffer layer may include a single layer or a multiple-layer stack, which may be formed by an electroplating process, a chemical electroplating process, a physical vapor deposition process or other suitable processes. The toughness of the buffer layer may range from 0.1 kilojoules per square meter (kJ/m²) to 100 kJ/m². A material of the buffer layer may include an organic material or an inorganic material, such as polyimide (PI) resin, parylene, benzocyclobutene (BCB), epoxy resin, polycarbonate (PC), polyethylene terephthalate (PET), polyethylene naphthalate (PEN), oxides, other suitable materials, or a combination thereof, but not limited thereto. For example, the buffer layer may be stacked in the following ways: organic-inorganic-organic, organic-organic-organic, and organic-organic-inorganic, etc. In some embodiments, in the cross-sectional view, the thickness of the buffer layer may range from 0.01 μm to 10 μm. The thickness of the buffer layer may refer to the maximum thickness of the buffer layer on the surface S1 of the substrate 10 in the vertical direction (the direction N1), or it may refer to the thickness of the buffer layer on the hole wall TW0 of the through hole TV0 in a horizontal direction (e.g., the horizontal direction HD1). In some embodiments, the ratio of the thickness of the buffer layer to the diameter D1 of the through hole TV0 may range from 0.02 to 0.2.

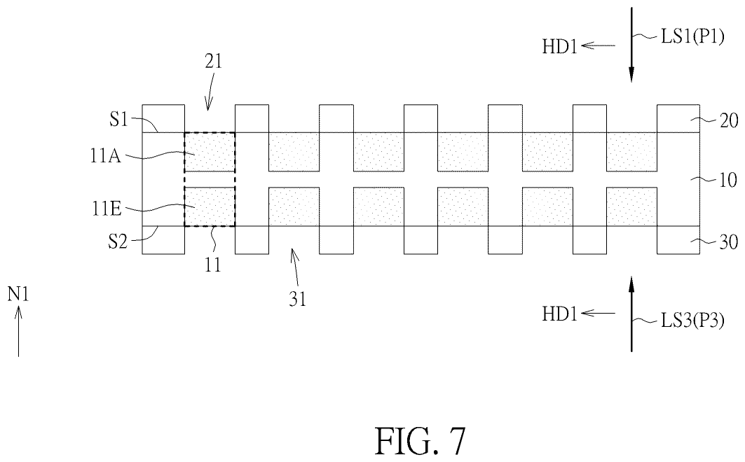

Please refer to FIG. 7, which is a cross-sectional schematic diagram showing a step of a method for manufacturing an electronic device according to another embodiment of the present disclosure. The difference between the present embodiment and the embodiment of FIG. 1 to FIG. 6 is that the present embodiment further includes steps as follows. A mask 30 is provided on the surface S2 of the substrate 10, wherein the surface S2 is opposite the surface S1. Next, the mask 30 is patterned to form an opening 31 in the mask 30, and the opening 31 exposes the corresponding portion 11 of the substrate 10, and then the energy P3 is provided to the corresponding portion 11 of the substrate 10 to perform a modification step, so as to form a modified region 11E in the substrate 10. In some embodiments, the mask 20 and the mask 30 may be formed first, the mask 20 and the mask 30 are patterned, and then the modification step is performed.

In this embodiment, the number of the openings 31 is the same as the number of the corresponding portions 11. That is, the number and the position of the openings 31 may correspond to that of the openings 21 and the corresponding portions 11. The energy P3 may be provided by irradiating the substrate 10 with the laser beam LS3. The direction of the laser beam LS3 irradiating the substrate 10 may be opposite to the direction of the laser beam LS1 irradiating the substrate 10, and the laser beam LS3 may scan the substrate 10 from right to left along the horizontal direction HD1 to modify the plurality of corresponding portions 11, so as to form a plurality of modified regions 11E respectively in the plurality of corresponding portions 11.

Next, the modification step by providing the energy (not shown) to the corresponding portion 11 of the substrate 10 may be repeated to form other modified regions (not shown) in the substrate 10, until the corresponding portion 11 of the substrate 10 is completely modified. It should be noted that as for the modified regions formed by irradiating the energy (or the laser beam) in the same direction (e.g. from top to bottom), the modified region formed in each time partially overlaps the previously modified region. Thereby, it is beneficial to increase the removal rate of the modified region in the subsequent etching process (see FIG. 4). In other words, the present embodiment can simultaneously provide the energy P1 and the energy P3 on two sides of the substrate 10 in the vertical direction (the direction N1) to modify the corresponding portion 11 of the substrate 10. On one hand, it is beneficial to shorten the time required to completely modify the corresponding portion 11, so as to improve the modification efficiency. On the other hand, it is beneficial to reduce the difference between the diameter D1 of the through-hole opening OP1 and the diameter D2 of the through-hole opening OP2 of the through hole TV0.

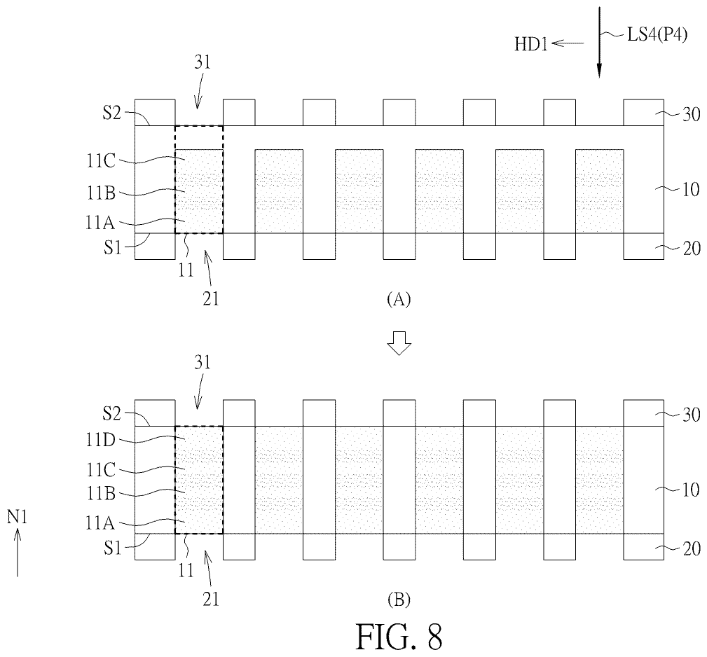

Please refer to FIG. 8, which is a cross-sectional schematic diagram showing a step of a method for manufacturing an electronic device according to yet another embodiment of the present disclosure. The main difference between the present embodiment and the embodiment of FIG. 7 is as follows. In the embodiment of FIG. 8, the energy is first provided from the side of the surface S1 to perform a plurality of modification steps, so as to sequentially form the modified region 11A, the modified region 11B and the modified region 11C in the corresponding portion 11. Afterward, the substrate 10 is turned over, as shown in the part (A) of FIG. 8, the energy P4 is provided from the side of the surface S2 instead, and the modification step is performed to modify the corresponding portion 11 of the substrate 10, so as to form the modified region 11D in the substrate 10. As shown in the part (B) of FIG. 8, the modified region 11D partially overlaps the modified region 11C. The energy P4 may be provided by irradiating the substrate 10 with the laser beam LS4. Thereby, it is beneficial to reduce the difference between the diameter D1 of the through-hole opening OP1 and the diameter D2 of the through-hole opening OP2 of the through hole TV0.

From the above embodiments, it can be seen that in the method for manufacturing the electronic device according to the present disclosure, when providing the energy to modify the substrate, the energy may be provided from one side of the substrate, or may be provided from two opposite sides of the substrate at the same time, or may be provided from one side of the substrate first, and then provided from the other side of the substrate after turning over the substrate. Moreover, the modification step may be repeated, until the corresponding portion is completely modified. In addition, when the energy is provided from two opposite sides of the substrate at the same time or in turn, the number of the modification steps, the energy, and the scanning direction of the energy on each side may be flexibly adjusted according to actual needs.

Please refer to FIG. 9, which is a cross-sectional schematic diagram of an electronic device 1A according to an embodiment of the present disclosure. In FIG. 9, the electronic device 1A is a package device as an example, but not limited thereto. The electronic device 1A includes a substrate 100 and a conductive layer 120, and may optionally include a marking element 130, a buffer layer 140, and a planarization layer 150. The substrate 100 has a through hole TV1. The conductive layer 120 includes a conductive element CM1, a pad CP1, and a pad CP2. The conductive element CM1 is disposed in the through hole TV1, the pad CP1 is disposed on the surface S1 of the substrate 100, and the pad CP2 is disposed on the surface S2 of the substrate 100. The conductive layer 120 is a double-layer structure as an example, which includes a seed layer 121 and a conductor layer 122. The marking element 130 is disposed in the substrate 100. The buffer layer 140 covers the surface S1 and the surface S2 of the substrate 100 and the hole wall (not label) of the through hole TV1. The number of the planarization layers 150 is two as an example. One of the planarization layers 150 is disposed on the surface S1 of the substrate 100 and is located between any two pads CP1. Moreover, the surface of the planarization layer 150 away from the substrate 100 is aligned with the surface of the pad CP1 away from the substrate 100. Another one of the planarization layer 150 is disposed on the surface S2 of the substrate 100 and is located between any two pads CP2. Moreover, the surface of the planarization layer 150 away from the substrate 100 is aligned with the surface of the pad CP2 away from the substrate 100. The substrate 100, the conductive layer 120, the marking element 130, the buffer layer 140 and the planarization layers 150 together form the substrate structure (not labeled).

The substrate 100 may be obtained by the aforementioned method of manufacturing the electronic device. For example, a modification step may be performed to the corresponding portion of the substrate 100 (i.e., the portion corresponding to the through hole TV1) by steps similar to that in FIG. 1 to FIG. 3, FIG. 7 or FIG. 8. Afterward, the corresponding portion may be removed by the etching process EP1 to obtain the through hole TV1 as shown in FIG. 4. In the cross-sectional view of the substrate 100, the hole wall of the through hole TV1 may have a wavy profile (see FIG. 6), and the wavy profile extends along the normal direction (the direction N1) of the substrate 100 or extends along the depth direction of the through hole TV1. For details of the through hole TV1, references may be made to the relevant descriptions of the through hole TV0.

The marking element 130 may be used to provide traceability and alignment functions. In some embodiments, the marking element 130 may be formed by providing the energy to modify the substrate 100. The aforementioned energy may be provided by a laser beam. There are distances between the marking element 130 and the surface S1 and the surface S2 of the substrate 100 in the vertical direction (the direction N1). Thereby, when the etching process EP1 as shown in FIG. 4 is performed to the substrate 100, the modified region corresponding to the marking element 130 is not removed. The marking element 130 may be pre-formed in the substrate 100 before the formation of the through hole TV1, or the marking element 130 may be formed in the substrate 100 after the through hole TV1 is formed. The implementation is not limited to either approach. For other details about the buffer layer 140 and the planarization layer 150, references may be made to the relevant descriptions above.

The electronic device 1A may further includes a circuit structure 200, an electronic unit 310 and an electronic unit 320. The circuit structure 200 is disposed on the substrate 100, and the electronic unit 310 and the electronic unit 320 are disposed on the circuit structure 200 and are electrically connected with the circuit structure 200.

The circuit structure 200 may include, for example, a redistribution layer (RDL) structure. Herein, the circuit structure 200 may include an insulating layer I1, a conductor layer C1 and a pad CP3. The conductor layer C1 is disposed in the insulating layer I1, for example, in the through hole or the blind hole of the insulating layer I1, so that the insulating layer I1 surrounds the conductor layer C1. The pad CP3 is disposed on the insulating layer I1 and is electrically connected with the conductor layer C1. In some embodiments, the pad CP3 may have a concave portion RP1, so that the bonding element CE1 may extend into the concave portion RP1 of the pad CP3, and the bonding strength between the bonding element CE1 and the pad CP3 may be improved.

The method for forming the circuit structure 200 may include steps as follows. First, an insulating material layer is formed on the surface S1 to cover the pad CP1. The insulating material layer may be formed through a coating process, but not limited thereto. At least one hole (not labeled) is formed in the insulating material layer to expose the pad CP1 below. For example, the hole may be formed by a photolithography process, but not limited thereto. Next, a seed layer (not shown) may be optionally formed to conformally cover the insulating material layer and in the hole. Next, a patterned photoresist (not shown) is formed on the seed layer to define the position of pad C1b, and the patterned photoresist has at least one opening to expose the seed layer. Next, a conductive film layer is formed on the exposed seed layer, and then the patterned photoresist and the seed layer located below the patterned photoresist are removed to complete the manufacture of the connecting element C1a and the pad C1b. Next, the above steps may be repeated to complete the manufacture of the connecting element C1c and the pad CP3. In some embodiments, an etching process or a surface treatment process may be performed to the pad CP3, so that the surface of the pad CP3 is roughened to form a concave portion RP1. The connecting element C1a, the pad C1b and the connecting element C1c together form the conductor layer C1, and the aforementioned multiple insulating material layers together form the insulating layer I1. In the circuit structure 200, the connecting element C1a and the connecting element C1c may serve as conductive wires in the vertical direction (the direction N1) to electrically connect pads located at different horizontal levels in the vertical direction (the direction N1). The pad C1b may serve as a connecting pad or as a conductive wire extending laterally. However, the present disclosure is not limited thereto.

A material of the insulating layer I1 may include an organic material or an inorganic material, such as polyimide (PI) resin, photosensitive polyimide (PSPI) resin, poly(p-phenylene benzobisoxazole (PBO), epoxy resin, polymer, acrylonitrile-butadiene-styrene (ABS), silicon oxide, silicon nitride, other suitable materials, or a combination thereof, but not limited thereto.

The conductor layer C1 and the pad CP3 are single-layer structures as an example, and the materials of the conductor layer C1 and the pad CP3 may independently include iron, aluminum, copper, nickel, tungsten, gold, platinum, other suitable materials or a combination thereof, but not limited thereto. According to an embodiment of the present disclosure, the materials of the conductor layer C1 and the pad CP3 may include copper. In other embodiments, the conductor layer C1 and the pad CP3 may be multi-layer structures. For example, each of the conductor layer C1 and the pad CP3 may optionally further include a seed layer (not shown), but not limited thereto. For the material of the seed layer, reference may be made to the relevant description above.

Herein, the electronic device 1A includes the electronic unit 310 and the electronic unit 320 as an example, but not limited thereto. The number of the electronic units of the electronic device 1A may be adjusted according to actual needs. When the electronic device 1A includes a plurality of electronic units, the types of the plurality of electronic units may be the same or different. The electronic unit 310 and the electronic unit 320 may be chips. The chips, for example, may be system on chips (SoC), dynamic random-access memory (DRAM) chips, high bandwidth memory (HBM) chips, photonic integrated circuits (PICs), application-specific integrated circuit (ASIC) chips, or other logic integrated circuit chips, but not limited thereto. The chip may include an active surface with a pad (such as the pads CP4 of the electronic unit 310 and the pads CP5 of the electronic unit 320) and a back surface opposite to the active surface. The pad, for example, may be an in-put/out-put pad (I/O pad). Herein, the chip faces the circuit structure 200 with the active surface, and the chip may be electrically connected with the circuit structure 200 through the pad (such as the pads CP4 of the electronic unit 310 and the pads CP5 of the electronic unit 320) of the active surface. In some embodiments, the electronic unit 310 and the electronic unit 320 may be unpackaged chips, but not limited thereto. In the present disclosure, the active surface may include an active element layer, such as a transistor and a related dielectric layer.

The electronic device 1A may further include a plurality of bonding elements CE1, and the plurality of bonding elements CE1 are disposed between the electronic unit 310 and the circuit structure 200 and between the electronic unit 320 and the circuit structure 200. The electronic unit 310, the electronic unit 320 and the circuit structure 200 may be electrically connected through the plurality of bonding elements CE1. The electronic device 1A may further include a filler UF1. The filler UF1 is disposed in gaps between the plurality of bonding elements CE1.

The electronic device 1A may further include an encapsulation layer 410. The encapsulation layer 410 surrounds the substrate 100, the circuit structure 200, the filler UF1, the electronic unit 310 and the electronic unit 320. The encapsulation layer 410 fills into the gap G1 between the electronic unit 310 and the electronic unit 320, and the encapsulation layer 410 does not cover the upper surface of the electronic unit 310 and the upper surface of the electronic unit 320. Thereby, the encapsulation layer 410 does not completely cover the electronic unit 310 and the electronic unit 320 or does not cover the upper surfaces of the electronic unit 310 and the electronic unit 320, which is beneficial for the heat dissipation of the electronic unit 310 and the electronic unit 320, but not limited thereto. The material of the encapsulation layer 410 may include, for example, an organic material or an inorganic material, such as epoxy, polymer, silicon oxide, silicon nitride, other suitable materials, or a combination thereof, but not limited thereto.

The electronic device 1A may further include a carrier 500. The carrier 500 is electrically connected with the circuit structure 200, and the circuit structure 200 and the carrier 500 are located on different sides of the substrate 100 in the normal direction (the direction N1) of the substrate 100. For example, the carrier 500 may be a printed circuit board (PCB), a package substrate, and a substrate like PCB (SLP), but not limited thereto. Any carrier capable of providing electrical connection function, such as a carrier including an insulating layer and a conductive wire disposed therein, may be used as the carrier 500 of the present disclosure. In some embodiments, the carrier 500 is another package device that is bonded to the substrate 100 through the bonding element CE2, thereby forming a structure similar to a 2.5D or a 3D package structure.

The electronic device 1A may further include a plurality of bonding elements CE2. The plurality of bonding elements CE2 are disposed between the substrate 100 and the carrier 500, and the circuit structure 200 is electrically connected with the carrier 500 through the conductive layer 120 (i.e., the conductive elements CM1) in the through holes TV1 and the bonding elements CE2. Herein, the bonding element CE2 is electrically connected with the conductive element CM1 through the pad CP2. In some embodiments, a surface of the pad CP2 facing toward the bonding element CE2 may be formed with a concave portion (not shown). Thereby, the bonding element CE2 may extend into the concave portion of the pad CP2, and the bonding strength between the bonding element CE2 and the pad CP2 may be improved. The electronic device 1A may further include a filler UF2. The filler UF2 is disposed in the gaps between the plurality of bonding elements CE2.

The materials of the bonding element CE1 and the bonding element CE2 may be the same or different. The bonding element CE1 and the bonding element CE2 may be made of conductive materials to provide a conductive function. The aforementioned conductive materials may include metals, such as tin, tin-silver, tin-silver-bismuth, tin-gold, tin-nickel-gold, nickel-gold, copper, other suitable materials, or a combination thereof, but not limited thereto. The conductive materials of the plurality of bonding elements CE1 and the plurality of bonding elements CE2 may be independently the same or different. The plurality of bonding elements CE1 and the plurality of bonding elements CE2 may independently be, for example, bumps, solder balls or pads, but not limited thereto. In this embodiment, a size of at least one of the plurality of bonding elements CE1 is less than a size of at least one of the plurality of bonding elements CE2. In addition, the sizes of the plurality of bonding elements CE1 may be the same, and the sizes of the plurality of bonding elements CE2 may be the same. The aforementioned “size” may refer to the maximum length of each of the bonding elements CE1 and the bonding elements CE2 in the horizontal direction (such as a direction perpendicular to the direction N1).

The filler UF1 and the filler UF2 may include a material with low hygroscopicity, and the material of the filler UF1 and the material of the filler UF2 may be the same or different. In some embodiments, the filler UF1 and the filler UF2 may independently include an organic material or an inorganic material, such as acrylic, epoxy resin, resin, photoresist material, other suitable materials, or a combination thereof, but not limited thereto. The filler UF1 and the filler UF2 may protect and fix the bonding elements CE1 and the bonding elements CE2, so that the probability of peeling off or poor electrical connection of the bonding elements CE1 and the bonding elements CE2 caused by the influence of moisture and/or external force can be reduced.

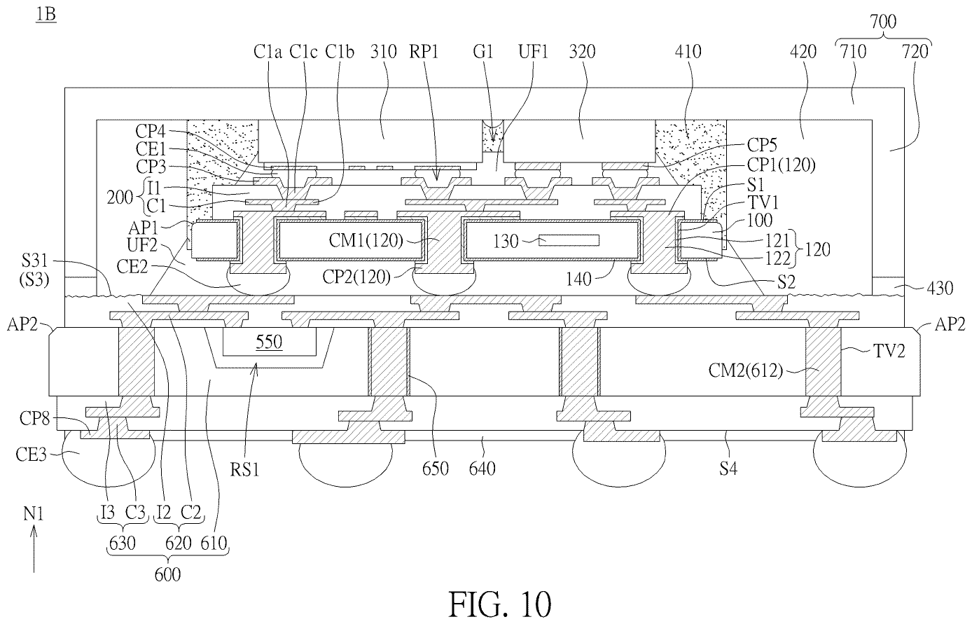

Please refer to FIG. 10, which is a cross-sectional schematic diagram of an electronic device 1B according to another embodiment of the present disclosure. The main differences between the electronic device 1B and the electronic device 1A are as follows. In the electronic device 1B, the carrier 500 of the electronic device 1A is replaced with a carrier 600. The electronic device 1B does not include the planarization layer 150, the substrate 100 further includes an edge structure AP1, and the electronic device 1B further includes an encapsulation layer 420, an adhesive layer 430, an electronic unit 550, a heat spreader 700, and bonding elements CE3.

In FIG. 10, the edge portion of the substrate 100 protrudes from the buffer layer 140 in a horizontal direction perpendicular to the vertical direction (the direction N1), so that a portion of the surface S1 and a portion of the surface S2 of the substrate 100 are not covered by the buffer layer 140. The substrate 100 may further include an edge structure AP1 disposed at the top edge of the substrate 100. The edge structure AP1 includes a fillet as an example, but not limited thereto. In other embodiments, the edge structure AP1 may include a chamfer. Thereby, it is beneficial to reduce the risk that the substrate 10 and the encapsulation layer 410 strip from each other.

The carrier 600 may include a substrate 610, a conductive layer (not labeled), a circuit structure 620, a circuit structure 630, a protective layer 640, and a buffer layer 650. In a direction perpendicular to the normal direction (the direction N1), the width (not labeled) of the substrate 610 is greater than the width (not labeled) of the circuit structure 620, and is greater than the width (not labeled) of the circuit structure 630. The width of the circuit structure 630 is between the width of the substrate 610 and the width of the circuit structure 620. The substrate 610 may further include an edge structure AP2 disposed at the top edge of the substrate 610. The edge structure AP2 includes a chamfer as an example, but not limited thereto. In other embodiments, the edge structure AP2 may include a fillet. The substrate 610 has a through hole TV2 and has a recess RS1. The substrate 610 may include a plurality of sub-substrates stacked along the normal direction (the direction N1), and the plurality of sub-substrates may have the same or different thicknesses. The plurality of sub-substrates may have the same or different coefficients of thermal expansion. The plurality of sub-substrates may have the same or different compositions. The buffer layer 650 partially covers the substrate 610. Herein, the buffer layer 650 covers the hole walls of the two through holes TV2 in the middle and surrounds the conductor layer 612. The conductive layer includes the conductive element CM2 disposed in the through hole TV2. The conductive layer is a single-layer structure as an example, and the conductive layer does not include a seed layer but only includes the conductor layer 612, but not limited thereto. In some embodiments, the conductive layer may further include a seed layer. For other details about the conductive layer, references may be made to the relevant descriptions of the conductive layer 40 and the conductive layer 120. According to some embodiments, the substrate 610 may include a plurality of sub-substrates stacked along the normal direction (the direction N1). The sub-substrates may be first formed with sub-through holes by the above steps and then be stacked sequentially. Alternatively, the sub-substrates may be stacked first and then the through hole is formed by the above steps. According to some embodiments, materials, widths, thicknesses, and coefficients of thermal expansion of the plurality of sub-substrates may be the same or different.

The substrate 610 may be manufactured by the aforementioned method for manufacturing the electronic device. In a cross-sectional view of the substrate 610, the hole wall of the through hole TV2 may have a wavy profile (see FIG. 6), and the wavy profile extends along the normal direction (the direction N1) of the substrate 610. For details of the substrate 610, references may be made to the relevant descriptions of the substrate 10 and the substrate 100.

The electronic unit 550 is disposed in the substrate 610 of the carrier 600. Specifically, a recess RS1 is formed in the substrate 610 for accommodating the electronic unit 550. The electronic unit 550 is electrically connected with the conductor layer C2 in the circuit structure 620. Thereby, the electronic unit 550 may be electrically connected with the electronic unit 310 and the electronic unit 320 through the circuit structure 620, the bonding elements CE2, the substrate 100, the circuit structure 200, and the bonding elements CE1. In addition, the electronic unit 550 may be electrically connected with other external elements (not shown) through the circuit structure 620, the substrate 610, the circuit structure 630, and the bonding elements CE3.

The electronic unit 550 may completely or partially overlap at least one of the electronic unit 310 and the electronic unit 320 in the vertical direction (the direction N1), which is beneficial to increase the maximum applied rate of planar space, so that the arrangement of the electronic elements in the electronic device 1B can be denser, and the current trend of miniaturization of electronic products can be satisfied. In addition, the electronic unit 550 may be connected with the electronic unit 310 and the electronic unit 320 via a conductive wire in the vertical direction (the direction N1), which is less likely to cause signal loss and can provide a better signal transmission effect compared to be connected via a conductive wire in the horizontal direction.

In some embodiments, the electronic unit 550 may be a passive element, such as a resistor, a capacitor, or an inductor, but not limited thereto. In some embodiments, the electronic unit 550 may be an active element, such as a chip of a different type from the electronic unit 310 and the electronic unit 320, but not limited thereto.

Each of the circuit structure 620 and the circuit structure 630 may include, for example, a redistribution layer (RDL) structure. Herein, the circuit structure 620 may include an insulating layer I2 and a conductor layer C2. The conductor layer C2 is disposed in the insulating layer I2, and the insulating layer I2 surrounds the conductor layer C2. The circuit structure 630 may include an insulating layer I3, a conductor layer C3, and a pad CP8. The conductor layer C3 is disposed in the insulating layer I3, and the insulating layer I3 surrounds the conductor layer C3. The pad CP8 is disposed on the insulating layer I3 and is electrically connected with the conductor layer C3. In some embodiments, the pad CP8 may have a concave portion (not shown), so that the bonding element CE3 may extend into the concave portion of the pad CP8, and the bonding strength between the bonding element CE3 and the pad CP8 can be improved. For details about the insulating layer I2, the insulating layer I3, the conductor layer C2, the conductor layer C3 and the pad CP8, references may be made to the relevant descriptions of the insulating layer I1, the conductor layer C1 and the pad CP3.

The protective layer 640 is disposed on the surface S4 of the circuit structure 630 away from the substrate 610. A portion of the protective layer 640 may be disposed in the gaps between the plurality of bonding elements CE3. The protective layer 640 may be configured to prevent moisture or contamination from entering into the metal lines of the circuit structure 630 and may be configured to define the sizes of the bonding elements CE3. According to an embodiment, the protective layer 640 may include an organic material, such as solder mask ink. Alternatively, the protective layer 640 may include an inorganic material, such as an oxide. The protective layer 640 has excellent moisture resistance. Specifically, the protective layer 640 may have a functional group with a double-bond polar structure, and good insulating characteristics can be formed through the resonance of the double bond. For example, the resistance value of the protective layer 640 may be greater than or equal to 1×10¹¹Ω and less than or equal to 5×10¹²Ω, but not limited thereto.

The plurality of bonding elements CE3 are disposed on the surface S4 of the circuit structure 630 away from the electronic unit 310 and the electronic unit 320, and are electrically connected with the conductor layer C3 in the circuit structure 630 through the pad CP8. The circuit structure 630 may be electrically connected with other external elements (not shown) through the bonding elements CE3. Optionally, the bonding element CE3 may partially or completely cover the sidewall of the pad CP8, or the bonding element CE3 may not cover the sidewall of the pad CP8. In addition, in a cross-sectional view of the electronic device 1B, the bonding element CE3 may be symmetrically disposed on the pad CP8 or asymmetrically disposed on the pad CP8. That is, the centerline (not shown) of the bonding element CE3 in the vertical direction (the direction N1) may coincide or not coincide with the centerline (not shown) of the pad CP8 in the vertical direction (the direction N1). For other details about the bonding elements CE3, references may be made to the relevant descriptions of the bonding elements CE1 and the bonding element CE2.

The heat spreader 700 may be configured to provide a heat dissipation function. The heat spreader 700 is disposed on the carrier 600, and the heat spreader 700 surrounds the substrate 100, the circuit structure 200, the electronic unit 310 and the electronic unit 320. Specifically, the heat spreader 700 may include a lid portion 710 and a sidewall portion 720, the sidewall portion 720 is connected with the lid portion 710, and the sidewall portion 720 may extend downwardly from the periphery of the lid portion 710 along the vertical direction (the direction N1) to form an accommodation space (not labeled). The substrate 100, the circuit structure 200, the electronic unit 310, the electronic unit 320, the bonding elements CE1, the bonding elements CE2, the filler UF1, the filler UF2, the encapsulation layer 410 and the encapsulation layer 420 are disposed in the accommodation space. The lid portion 710 is disposed on the upper surfaces of the electronic unit 310 and the electronic unit 320 and directly contacts the upper surfaces of the electronic unit 310 and the electronic unit 320, and the sidewall portion 720 surrounds and directly contacts the encapsulation layer 420. A material of the heat spreader 700 may include, for example, a metal, silicon, silicon carbide, graphite, graphene, other suitable materials, or a combination thereof, but not limited thereto.

The adhesive layer 430 is disposed between the heat spreader 700 and the surface S3 of the circuit structure 620. With the adhesive layer 430, the heat spreader 700 may be fixed on the carrier 600. In some embodiments, the adhesive layer 430 may be a heat dissipation adhesive material and can provide a heat dissipation function. In some embodiments, the surface S3 may be roughened by a surface treatment process to form a rough portion S31. Thereby, the bonding strength between the adhesive layer 430 and the surface S3 may be strengthened, and the fixed relationship between the heat spreader 700 and the carrier 600 may be strengthened accordingly. A material of the adhesive layer 430 may include an acrylic-based resin, a urethane-based resin, other suitable materials, or a combination thereof, but not limited thereto.

The encapsulation layer 420 is disposed in the space between the encapsulation layer 410, the filler UF2, and the heat spreader 700. For details about the encapsulation layer 420, references may be made to the relevant description of the encapsulation layer 410 above. The materials of the encapsulation layer 420 and the encapsulation layer 410 may be the same or different. For other details about the electronic device 1B, references may be made to the relevant descriptions of the electronic device 1A, and are omitted herein.

Compared with the prior art, in the method for manufacturing the electronic device according to the present disclosure, with the second modification region overlapping the first modification region, it is beneficial to reduce the probability of incomplete modification for the portion of the substrate to form the through hole, and can optimize the shape of the through hole and improve the yield of the electronic device. In some embodiments, the diameters of the two through-hole openings of the through hole are configured to have a small difference. For example, the absolute value of the difference between the diameters is configured to be less than or equal to 3 μm. Thereby, the shape of the through hole may be further optimized.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for manufacturing an electronic device, comprising:
providing a substrate;
providing a first mask on a first surface of the substrate;
patterning the first mask to form a first opening in the first mask, wherein the first opening exposes a corresponding portion of the substrate;
providing a light source comprising a first energy to the corresponding portion of the substrate to perform a first modification step, so as to form a first modified region in the substrate; and
providing another light source comprising a second energy to the corresponding portion of the substrate to perform a second modification step, so as to form a second modified region in the substrate,
wherein the second modified region at least partially overlaps the first modified region.

2. The method for manufacturing the electronic device of claim 1, wherein in a cross-sectional view of the substrate, the first modified region and the second modified region have an overlapping area, and a proportion of the overlapping area in the first modified region ranges from 5% to 20%.

3. The method for manufacturing the electronic device of claim 1, wherein a ratio of the first energy to the second energy ranges from 0.8 to 1.2.

4. The method for manufacturing the electronic device of claim 1, further comprising:
removing the first modified region and the second modified region to form a through hole in the substrate, wherein the substrate further has a second surface opposite to the first surface, and the through hole has a first through-hole opening on the first surface and a second through-hole opening on the second surface; and
removing the first mask.

5. The method for manufacturing the electronic device of claim 4, wherein the first modified region and the second modified region are removed through an etching process.

6. The method for manufacturing the electronic device of claim 4, wherein the first through-hole opening has a first diameter, the second through-hole opening has a second diameter, and when an absolute value of a difference between the second diameter and the first diameter is greater than 3 micrometers (μm), the method for manufacturing the electronic device further comprises:
performing a rework step, wherein the substrate is subjected to a local etching process or a local laser process, so that the absolute value of the difference between the second diameter and the first diameter is equal to or less than 3 μm.

7. The method for manufacturing the electronic device of claim 4, further comprising:
providing a conductive layer disposed in the through hole.

8. The method for manufacturing the electronic device of claim 7, before providing the conductive layer disposed in the through hole, further comprising:
providing a buffer layer to cover at least one of the first surface, the second surface and a hole wall of the through hole of the substrate.

9. The method for manufacturing the electronic device of claim 7, further comprising:
performing a planarization process to the conductive layer.

10. The method for manufacturing the electronic device of claim 1, further comprising:
providing a second mask on a second surface of the substrate, wherein the second surface is opposite to the first surface;
patterning the second mask to form a second opening in the second mask, wherein the second opening exposes the corresponding portion of the substrate; and
providing a third energy to the corresponding portion of the substrate to perform a third modification step, so as to form a third modified region in the substrate.

11. An electronic device, comprising:
a substrate having a through hole, wherein in a cross-sectional view of the substrate, a hole wall of the through hole has a wavy profile, and the wavy profile extends along a normal direction of the substrate; and
a conductive layer disposed in the through hole.

12. The electronic device of claim 11, wherein the wavy profile comprises a first convex portion, a concave portion and a second convex portion disposed sequentially along the normal direction, the first convex portion and the second convex portion protrudes toward the through hole in a radial direction of the through hole, and the concave portion concaves away from the through hole in the radial direction of the through hole.

13. The electronic device of claim 11, wherein the hole wall of the through hole has a surface roughness greater than or equal to 0.1 μm and less than or equal to 1.5 μm.

14. The electronic device of claim 11, wherein the substrate has a first surface and a second surface disposed opposite to the first surface, the through hole has a first through-hole opening on the first surface, the through hole has a second through-hole opening on the second surface, the first through-hole opening has a first diameter D1, the second through-hole opening has a second diameter D2, and a following condition is satisfied: |D2−D1|≤3 μm.

15. The electronic device of claim 11, wherein the substrate has a first surface and a second surface disposed opposite to the first surface, the through hole has a first through-hole opening on the first surface, the through hole has a second through-hole opening on the second surface, the electronic device further comprises a buffer layer, and the buffer layer covers at least one of the first surface, the second surface and a hole wall of the through hole of the substrate.

16. The electronic device of claim 11, further comprising:
a circuit structure disposed on the substrate; and
a first electronic unit disposed on the circuit structure and electrically connected with the circuit structure.

17. The electronic device of claim 16, further comprising:
a carrier electrically connected with the circuit structure, wherein the circuit structure and the carrier are located on different sides of the substrate in the normal direction.

18. The electronic device of claim 17, further comprising:
a bonding element disposed between the substrate and the carrier, wherein the circuit structure is electrically connected with the carrier through the conductive layer in the through hole and the bonding element.

19. The electronic device of claim 17, further comprising:
a heat spreader disposed on the carrier, wherein the heat spreader surrounds the substrate, the circuit structure and the first electronic unit.

20. The electronic device of claim 17, further comprising:
a second electronic unit disposed in the carrier.
